(19) United States
(12) Patent Application Publication
(10) Pub. No.: US 2025/0204286 A1
(43) Pub. Date: Jun. 19, 2025

(54) INTEGRATED CIRCUIT COMPRISING A NON-VOLATILE MEMORY AND METHOD FOR MANUFACTURING THE SAME

(71) Applicant: COMMISSARIAT A L'ENERGIE ATOMIQUE ET AUX ENERGIES ALTERNATIVES, PARIS (FR)

(72) Inventors: Guillaume BOURGEOIS, GRENOBLE CEDEX 09 (FR); Jean-Baptiste DORY, GRENOBLE CEDEX 09 (FR); Joël MINGUET LOPEZ, GRENOBLE CEDEX 09 (FR); Gabriele NAVARRO, GRENOBLE CEDEX 09 (FR)

(21) Appl. No.: 18/980,511

(22) Filed: Dec. 13, 2024

(30) Foreign Application Priority Data
Dec. 14, 2023 (FR) FR2314206

(51) Int. Cl. H10N 70/00; H10B 63/00; H10B 63/10

(52) U.S. Cl. CPC H10N 70/8413; H10B 63/10; H10B 63/24; H10N 70/021; H10N 70/063; H10N 70/882; H10N 70/883

(57) ABSTRACT

One aspect of the invention relates to an integrated circuit (1) comprising:
a copper via (42); and
a non-volatile memory (5), electrically connected to the copper via (42),
   the integrated circuit is remarkable in that it comprises a copper diffusion barrier (6), based on Ta, Ti or Co, extending as a layer against the copper via, the non-volatile memory being connected to the via through the diffusion barrier.

### TECHNICAL FIELD OF THE INVENTION

The technical field of the invention relates to integrated circuits comprising non-volatile memories and more particularly implementing a Phase Change Material, referred to as a PCM memory. The technical field relates to integrated circuits that can be implemented in the automotive field, for example.

### TECHNOLOGICAL BACKGROUND OF THE INVENTION

A non-volatile memory implementing a phase change material (PCM) can be characterised by its resistance, which can take at least two distinct values. Each resistance value corresponds to a distinct state that the memory can assume, thus enabling binary information to be stored. A high resistance value corresponds to a “RESET” state, generally associated with a low state or “0”. A low resistance value corresponds to a state referred to as “SET”, generally associated with a high state or “1”.

The memory can be programmed from one state to another, or from one resistance value to another, using steps referred to as “RESET” or “SET” programming.

“RESET” programming is based on melting of all or part of the volume of the phase-change material (a chalcogenide, for example), which is achieved by an electrical pulse with a sufficiently high current. The current is dimensioned to enable a melting temperature of the PCM material to be reached by Joule effect. Sudden cooling, obtained by virtue of a rapid reduction in the current applied, leaves the molten part of the PCM material in an amorphous state. This amorphous arrangement has a high resistance, corresponding to the RESET state.

“SET” programming is based on obtaining a crystalline state of the PCM material. This operation consists in applying an electrical pulse which produces, by the Joule effect, a partial or total melting of the PCM material. A gradual reduction in the current applied allows the PCM material to recrystallise. This crystalline state, with its lower resistance, corresponds to the SET state.

Information retention can be characterised by how long the RESET state is maintained as a function of time and temperature. Information retention specifications can be strict for embedded applications. For example, a standard referred to as “JEDEC”, applied to the automotive industry, requires the RESET state to be stable for two years at a temperature of 150° C.

Document [“Optimization Metrics for Phase Change Memory (PCM) Cell Architectures”, M. Boniardi & al., IEDM14 IEEE 2014] discloses a non-volatile memory comprising a layer of PCM material and a heater connected in series. The heater is especially of the “WALL” type, i.e. having a fin shape, extending perpendicularly to the plane of the layers. Thus the contact between the PCM layer and the heater is small, enabling high current densities to be achieved at the contact point. The temperatures accessible with this type of heater make it possible to improve programming efficiency of the PCM layer. Document also discloses that the PCM layer/heater assembly is connected in series between two electrodes of metal, herein tungsten. Applying an electrical potential to the terminals of the tungsten electrodes causes an electrical current to circulate which, by Joule effect in the resistive heater, causes localised heating of the PCM layer.

Document [“High Density Embedded PCM in 28 nm FDSOI Technology for Automotive Micro-Controller Applications”, F. Arnaud & al, IEDM20 IEEE 2020] discloses a non-volatile memory embedded in an integrated circuit, comprising a PCM layer shared between several heating elements, referred to as WALL-type “heaters”. Each heating element is connected in series with an electrode, distinct for each heating element, and the PCM layer. This arrangement of the memories enables them to be brought closer to the “Back-End-Of-Line (BEOL) functional block” of the integrated circuit, also referred to as the “secondary manufacturing level”, by disposing them under a first routing level. In this way, the non-volatile memories can be separated from the “Front-End Of Line (FEOL) functional block” of the integrated circuit, also referred to as the “primary manufacturing level”, wherein logic circuits, for example of the “CMOS” (Complementary Metal Oxide Semiconductor) type, are integrated.

The electrical connection between the different levels of the integrated circuit, i.e. between the logic circuits of the FEOL and the memories of the different levels of the BEOL, is made by means of routing levels comprising copper vias, passing through the different levels of the circuit. Integrating the PCM layer in the vicinity of copper vias is problematic, however. Indeed, copper is an element that can degrade PCM layers. In addition, copper diffusion can be assisted by temperature. Thus, manufacturing memories or the flow of current in the heating elements assists copper diffusion and can cause degradation of the PCM layers. There is therefore a need to integrate a PCM layer into the BEOL while avoiding the pitfalls related to copper diffusion.

In this context, document [“18 nm FDSOI Technology Platform embedding PCM & Innovative Continuous-Active Construct Enhancing Performance for Leading-Edge MCU Application”, D. Min & al, IEDM21 IEEE 2021] also discloses a non-volatile memory embedded in an integrated circuit, comprising a PCM layer shared between several WALL-type heating elements. Each heating element is herein connected in series between a tungsten contact referred to as a “plug” and the PCM layer.

Forming the plug, however, involves several manufacturing steps. In addition, its great thickness rises problems of integration in the BEOL where the thickness between the different levels within an integrated circuit can be restricted.

### SUMMARY OF THE INVENTION

There is a need to provide an integrated circuit aimed at solving, at least in part, the aforementioned problems. For this, the invention provides a means of blocking copper diffusion between a routing level and a memory which may be impacted by copper diffusion, having a small thickness and being simple to manufacture.

The invention more particularly relates to an integrated circuit comprising:
a substrate having a planar surface;
at least one via or row, of copper, extending in the substrate and opening onto the planar surface of the substrate, by exposing a surface referred to as the “contact surface”;
at least one non-volatile memory comprising:
   a first electrode, referred to as the “heating element”;
   a second electrode, referred to as the “top electrode”; and a first active layer between the heating element and the top electrode, electrically connected to the top electrode and the heating element,
      the integrated circuit being remarkable in that it comprises at least one copper diffusion barrier based on tantalum or titanium or cobalt or alloys thereof, said at least one diffusion barrier extending in the form of a layer against at least one part of the contact surface of said at least one via or of said at least one row, the heating element of said at least one non-volatile memory being in contact with the first active layer of said at least one non-volatile memory and in contact with said at least one diffusion barrier.

By planar surface, it is meant a surface extending in a plane (for example a horizontal plane).

By via, it is meant a conductive track extending in the substrate, for example along a direction perpendicular to the surface of the substrate. By row, it is meant a conductive track extending in the substrate, for example along a direction parallel to the surface of the substrate.

By “active layer”, it is meant a layer whose resistance can reversibly or irreversibly vary as a result of flow of a current or the application of a heat treatment. Preferably, the first active layer can change resistance between at least two distinct values, in a bistable manner, enabling information to be stored.

By non-volatile memory, it is meant preferably a phase-change memory.

By “parallel” and “perpendicular”, it is meant respectively parallel to within 20°, or even parallel to within 10°, and perpendicular to within 20°, or even perpendicular to within 10°.

By “based on an element”, it is meant preferably comprising at least 50% of this element.

“In contact” means that there is no intermediate element between the elements in contact. Typically, there is no intermediate layer between two elements in contact, especially between the heating element and the first active layer, or between the volatile memory and the diffusion barrier.

Each barrier layer prevents the copper diffusion to the memory and/or to the heating element upon manufacturing or using the integrated circuit. This layer replaces the use of a tungsten plug.

The diffusion barrier makes it possible to manufacture the non-volatile memory at the BEOL of the integrated circuit and therefore to keep it away from the logic circuits of the FEOL of the integrated circuit. This arrangement prevents the non-volatile memory from disturbing the operation of the FEOL logic circuits.

In addition, materials based on Ta, Ti and Co are sufficiently effective at blocking copper diffusion while making it possible to provide diffusion barrier in the form of a thin layer. Thus, unlike a tungsten plug, which is very thick, the diffusion barriers according to the invention make it possible to significantly reduce the overall height of each non-volatile memory. Barriers based on Ta, Ti or Co offer easier integration of non-volatile memories. They allow the resulting integrated circuit to be used at a higher frequency. Indeed, the height between the different levels of the BEOL can be restricted by the height of the non-volatile memories. Reducing the height of the memories reduces the thickness between the different levels of the BEOL. The length of the copper vias connecting these levels can then also be reduced. Thus the resistance of each via and the capacitive coupling between vias is reduced, allowing use of the circuit at higher frequencies.

Diffusion barriers can be implemented at different levels of the integrated circuit, for example as close as possible to the FEOL.

Advantageously, for each non-volatile memory, each heating element comprises a portion, referred to as a “fin”, extending perpendicularly to the surface of the substrate and comprising a first end, in contact with the first active layer of said non-volatile memory, and a second end, in contact with said at least one diffusion barrier.

Advantageously, each diffusion barrier extends against the entire contact surface of a via or said at least one copper row. Thus, diffusion blocking is improved. This also avoids the need for a complementary solution to reduce copper diffusion from a portion of the contact surface of each via or row that would not be covered with the diffusion barrier. According to one development, each diffusion barrier extends beyond said contact surface by also extending over the planar surface of the substrate.

Advantageously, each heating element comprises a material from: TiN, TiC, TiSiN, TiSiCN, TiWN, TaN and TaCN.

Advantageously, the first active layer of each volatile memory comprises a chalcogenide material. Thus the first layer is programmable.

According to one embodiment, the integrated circuit comprises:
a plurality of non-volatile memories; and
a plurality of diffusion barriers, spaced apart from each other;
a plurality of copper vias or copper rows, each via or row extending in the substrate and opening onto the surface of the substrate by exposing a contact surface, said contact surfaces being arranged in a matrix,
   each diffusion barrier extending as a layer against at least one part of the contact surface of one of the vias or rows, the heating element of each non-volatile memory being connected to one of the diffusion barriers.

Advantageously, the first active layers of the different non-volatile memories are laterally insulated from each other. By “laterally insulated”, it is meant that the first active layers are without direct contact.

According to one alternative embodiment, a same first active layer is continuous and common to at least two non-volatile memories, said same first active layer being in contact with each heating element of said at least two non-volatile memories. The first active layers can thus be shared between several non-volatile memories. This makes it possible, for example, to reduce the number of operations required to make the first active layers, in particular the number of etching operations.

According to one embodiment, the integrated circuit comprises a selection element associated with said at least one non-volatile memory. This allows addressing of each memory. This configuration makes it possible to have a selector in the BEOL, with each memory. This arrangement makes it possible to dispense with the use of a logic component, for example a CMOS transistor in the FEOL, as a selector. This arrangement thus dispenses with the technology implemented in the FEOL and makes each memory portable.

Advantageously, the selection element is an Ovonic Threshold Switch (OTS), preferably comprising an alloy based on Ge, Sb, Se, As, Si, Te, S or Al, which may be doped, such as GeSbSe, GeSe, AsSeSiGe, AsSe, SbSe, SiSe, AsTe, SiGeSe or AlTe alloys.

Advantageously, the integrated circuit is free of tungsten via or metal via in contact with said at least one copper via or said at least one copper row and the heating element of said at least one non-volatile memory.

Advantageously, the at least one diffusion barrier is a planar bilayer, the planar bilayer comprising TaN in contact with the via or row, and comprising Ta in contact with the heating element.

The invention also relates to a method for manufacturing an integrated circuit comprising the steps of:
providing:
   a substrate having a planar surface; and
   at least one via or at least one row, of copper, extending in the substrate and opening onto the planar surface of the substrate, by exposing a surface referred to as the “contact surface”,
forming at least one copper diffusion barrier based on tantalum or titanium or cobalt or alloys thereof, so that said at least one diffusion barrier extends in the form of a layer against at least one part of the contact surface of said at least one via or said at least one row;
forming at least one non-volatile memory comprising:
   a first electrode, referred to as the “heating element”, being in contact with said at least one diffusion barrier;
   a second electrode, referred to as the “top electrode”; and
   a first active layer between the heating element and the top electrode, electrically connected to the top electrode and in contact with the heating element.

Forming a plug, for example of tungsten, requires five additional steps, especially comprising a chemical-physical polishing step. Forming diffusion barriers requires at most two steps (for example depositing and delimiting a layer). The number and complexity of the steps are reduced.

According to one embodiment, manufacturing each diffusion barrier comprises the step of growing said diffusion barrier by selectively depositing tantalum or titanium or cobalt or alloys thereof onto the contact surface of a copper via or a copper row.

Thus growth by selective deposition makes it possible to locate growth of diffusion barriers at the contact surface of copper via or rows.

According to one alternative implementation, manufacturing the diffusion barrier comprises the steps of:
depositing a layer based on tantalum or titanium or cobalt or alloys thereof, referred to as a “barrier material layer”, onto the planar surface of the substrate and the contact surface of said at least one via or of said at least one copper row;
etching the barrier material layer through at least one etch mask, with stopping on the substrate, so as to form the at least one diffusion barrier.

Advantageously, in order to form a plurality of diffusion barriers, etching the barrier material layer is made in such a way as to form separate diffusion barriers.

Advantageously, etching the barrier material layer through said at least one mask is made so that each diffusion barrier extends as a layer against at least one part of the contact surface of said at least one via or said at least one row.

Advantageously, forming each non-volatile memory comprises the steps of:
forming, before the step of etching the barrier material layer, a first dielectric layer extending over the barrier material layer, leaving free at least one portion of the barrier material layer, said first dielectric layer comprising at least one flank extending perpendicularly to the planar surface of the substrate, in vertical alignment with the contact surface of said at least one via or of said at least one row;
conformally depositing a resistive layer onto the first dielectric layer and onto said at least one free portion of the barrier material layer;
anisotropically etching the resistive layer, perpendicularly to the planar surface of the substrate, with stopping on the barrier material layer, so as to leave a portion of the resistive layer, referred to as a “fin”, extending perpendicularly to the planar surface of the substrate, from the barrier material layer, against the flank of the first dielectric layer and in vertical alignment with the contact surface of said at least one via or said at least one row;
anisotropically etching the barrier material layer through a first etch mask, with stopping on the substrate, the first etch mask comprising the first dielectric layer and the fin;
anisotropically etching the fin and the barrier material layer through a second etch mask, with stopping on the substrate, so as to delimit each diffusion barrier from the barrier material layer, at a part of the contact surface of said at least one via or of said at least one row, and so as to delimit each first electrode, referred to as the “heating element”, from the fin, as an extension of a diffusion barrier.

By conformally depositing the resistive layer onto the first dielectric layer, a resistive layer is formed having portions parallel to the substrate and a portion perpendicular to the substrate. The parallel portions of the resistive layer are removed by etching. The perpendicular portion of the resistive layer is retained because its thickness, measured perpendicular to the substrate, is much greater than that of the parallel portions. This perpendicular portion thus forms the fin.

The first etch mask and the fin extending against the flank of the first dielectric layer then form a first etch mask protecting part of the barrier material layer from etching. Thus the fin is at least one in contact with the part of the barrier material layer which it protects from etching.

Etching through the second mask delimits each diffusion barrier and each heating element in the extension of a via or row.

Advantageously, forming each non-volatile memory comprises the steps of:
depositing, before etching the fin and the barrier material layer through the second etch mask, a first active layer extending in parallel to the planar surface of the substrate and in contact with each fin;
etching the first active layer through the second etch mask so as to delimit the first active layer in the extension of a heating element and a diffusion barrier.

Each non-volatile memory thus comprises a first active layer aligned with a heating element. Coupling between the first active layer and the heating element is therefore controlled and identical for different non-volatile memories. This alignment also makes it possible to eliminate spatial drift due to several etching steps made at different levels. In addition, the non-volatile memory is also aligned with a diffusion barrier, ensuring effective protection of the first active layer from copper.

Advantageously, when the method forms two volatile memories, the second etch mask is configured so that the first active layers of the two non-volatile memories form one and the same layer.

The first two active layers form an island or a row, for example.

Advantageously, forming each non-volatile memory comprises:
depositing a first metal layer onto the first active layer before etching the first active layer through the second etch mask;
etching the first metal layer through the second etch mask so as to delimit each top electrode, as an extension of a heating element and a diffusion barrier.

Advantageously, the method also comprises the step of forming a selection element associated with each non-volatile memory, in contact with the top electrode of each non-volatile memory.

Advantageously, the at least one diffusion barrier is etched a first time along a first direction upon forming the heating element, and a second time along a second direction, different from the first direction, upon forming, for example by etching, the top electrode.

### BRIEF DESCRIPTION OF THE FIGURES

The invention and its different applications will be better understood upon reading the following description and upon examining the accompanying figures. The figures are set forth by way of indicating and in no way limiting the purposes of the invention.

FIGS. 1A, 1B, 2 and 3 show the first, second and third embodiments of an integrated circuit according to the invention. FIG. 1B is an enlargement of FIG. 1A.

FIGS. 4, 5, 6, 7, 8, 9, 10, 11, 12, 13, 14, 15, 16, 17 and 18 show a first implementation of a manufacturing method according to the invention, for obtaining the integrated circuit of FIGS. 1A and 1B.

FIGS. 19, 20, 21 and 22 show a second implementation of the manufacturing method according to the invention, for obtaining the integrated circuit of FIG. 3.

FIGS. 23, 24 and 25 show a third implementation of the manufacturing method according to the invention, for obtaining the integrated circuit of FIG. 2.

Unless otherwise specified, a same element appearing in different figures has a single reference.

### DETAILED DESCRIPTION

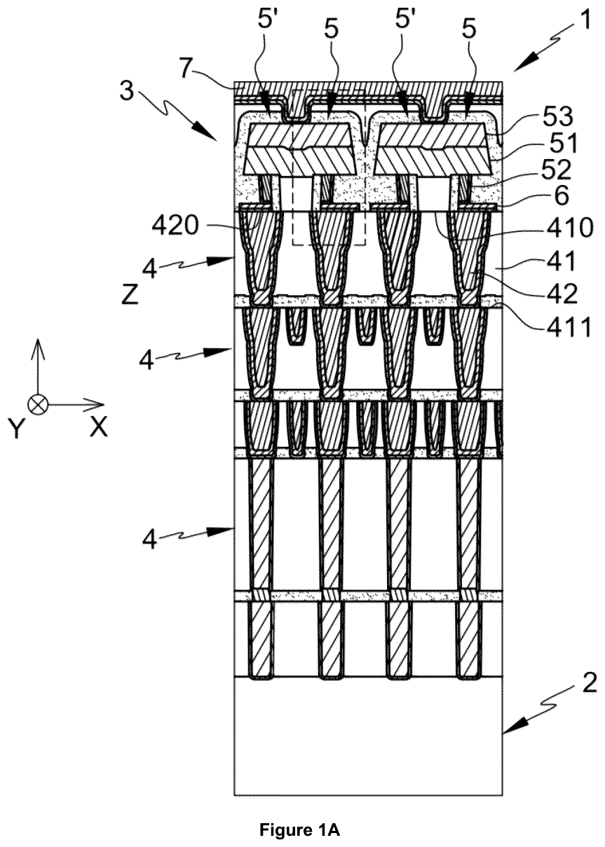

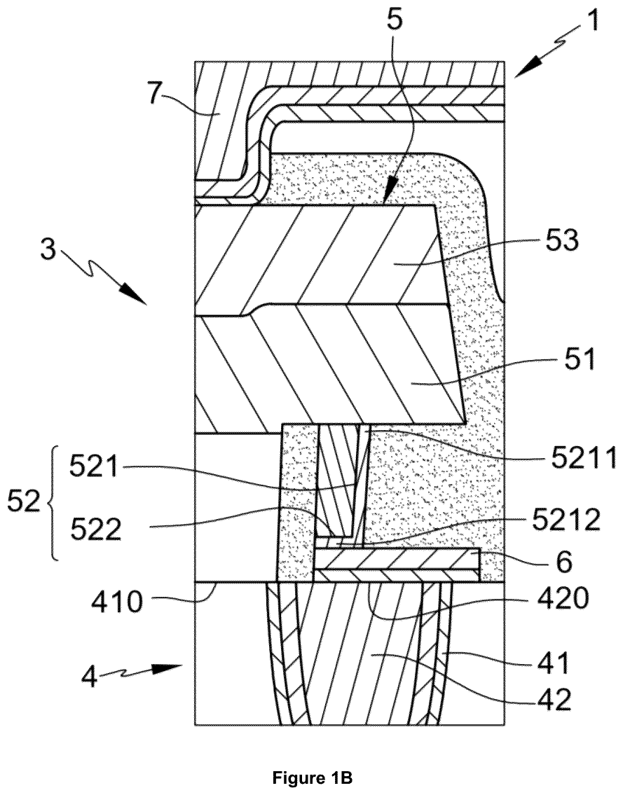

FIGS. 1A and 1B show an integrated circuit 1 according to a first embodiment of the invention. FIG. 1B corresponds to an enlargement of FIG. 1A, depicted as a dashed rectangle. The circuit 1 comprises two functional blocks 2, 3, also referred to as functional levels, which are the FEOL 2 (also simply referred to as “front-end” or “FEND”) and the BEOL 3 (also simply referred to as “back-end”). This type of integrated circuit arrangement or architecture is known to those skilled in the art.

The integrated circuit 1 comprises at least one non-volatile memory 5, 5′. In the embodiment of FIGS. 1A and 1B, it comprises two groups of two non-volatile memories 5, 5′. The memories 5, 5′ are disposed in the back-end 3 of the circuit 1.

They are electrically connected to the front-end 2 of the circuit 1 through at least one copper routing level 4, herein a plurality of levels 4 in this embodiment. Thus, the memories 5, 5′ can be connected to logic components of the front-end 2 acting, for example, as a selector for the different memories 5, 5′.

Alternatively, the memories could also be located directly on the front-end 2 (in a level that could be referred to as the “metal level”) and directly in contact with the logic components of the front-end 2.

In the example illustrated, each routing level 4 of FIGS. 1A and 1B comprises a substrate 41 and several vias 42. The substrate 41 has two planar surfaces 410, 411, opposite to each other, referred to as the “top surface” and the “bottom surface”. They extend herein in a plane {X; Y}. Each via 42 of a routing level 4 passes right through the substrate 41, joining the bottom surface 411 of the substrate 41 to the top surface 410 of the substrate 41. More particularly, the vias 42 emerge from each planar surface 410, 411 by exposing a surface 420 referred to as the “contact surface”. Each contact surface 420 of the vias 42 is for example parallel and aligned with the planar surfaces 410, 411 of the substrate 41. By “aligned»>, it is meant aligned to within 2 nm, preferably less.

Alternatively, the routing level 4 may comprise rows extending in the substrate 41 and exposing at least one surface area equivalent to the contact surface 420 of the vias 42. To simplify the description, only embodiments having vias 42 will be set forth.

The contact surfaces 420 make it possible to make electrical contact with different elements such as a via 42 or a row of an adjacent routing level 4, a heating element 52 of a memory 5 or even a logic component of the front-end 2.

The memories 5, 5′ illustrated in FIGS. 1A and 1B comprise a first active layer 51 enabling information to be stored. By virtue of an internal change induced by a current flow or a heat treatment, an active layer 51 makes it possible to exhibit a sufficiently large difference in electrical resistance to be measurable and usable for storing information.

In the particular case of the invention, the first active layer 51 preferably comprises a phase-change material for which a heat treatment comprising more or less brief cooling makes it possible to freeze a particular crystalline state. The active layer comprises a chalcogenide material. This is, for example, an alloy of GeₓSb_{y}Te_{z} (with x+y+z=100%) such as Ge₁Sb₂Te₄, GeTe, Sb₂Te₃. The GeₓSb_{y}Te_{z} alloy may also comprise other elements of interest as, for example: N, C, O, Si, Se, Bi, In or even As.

The object of the invention is relevant to a phase change material because these materials are sensitive to copper diffusion. The object of the invention can also be extended to other active materials that can be disturbed or degraded by the presence of copper. These include, for example:
so-called conductive bridge materials (used in a Conductive Bridge RAM (CBRAM)), implementing the formation/dissolution of a conductive filament in a solid electrolyte following the diffusion of ions from an active electrode;
a “reversible oxide breakdown” material (used in an Oxide RAM (OxRAM)), implementing reversible breakdown of a dielectric material as a function of an electrical voltage applied to this material; or even
a magnetic material (used in a Magnetic RAM (MRAM)), implementing a reversal of magnetisation as a function of a current flow therethrough.

In the embodiment of FIGS. 1A and 1B, each memory 5, 5′ comprises a first electrode 52, referred to as the “bottom electrode”, or “heating element” or “heater” or even “conductive finger”, electrically connected to the first active layer 51. Each memory 5, 5′ also comprises a second electrode 53, referred to as the “top electrode”, also electrically connected to the first active layer 51. The first active layer 51 is connected in series between the heating element 52 and the top electrode 53.

In this embodiment, each heating element 52 is of the “WALL” type. The principle of a heating element of this type and how it is connected to an active layer is described in document [“Optimization Metrics for Phase Change Memory (PCM) Cell Architectures”, M. Boniardi & al., IEDM14, IEEE 2014].

A heating element 52 of the “WALL” type is remarkable in that it comprises at least one first portion 521, referred to as a “fin”, extending perpendicularly to the planar surface 410 of the substrate 41 (in other words according to a direction Z).

The manufacture of a WALL-type heating element 52 may frequently involve the presence of a second portion 522, referred to as the “heating element leg” or simply “leg”, consecutive to the fin 521 and extending in parallel to the planar surface 410 of the substrate 41 (in other words in the {X; Y} plane). The leg 522 is preferably absent, in order to bring the memories 5, 5′ closer together and increase the density of information storage per unit area.

Each heating element 52 can be made from one of the following resistive materials: TiN, TiC, TiSiN, TiSiCN, TiWN, TaN and TaCN.

The first active layer 51 is connected to one of the ends 5211 of the fin 521. This small contact improves the efficiency of the heat treatment that can be applied to the first active layer 51. It makes it possible to program this layer 51 with reduced energy consumption.

The leg 522 of the heating element 52 is electrically connected, on the one hand, to a contact surface of a via 42 of a routing level 4 (but not directly in contact with this surface 420) and, on the other hand, to a second end 5212 of the fin 521.

The vias 42 of the routing levels 4 in FIGS. 1A and 1B are of copper. The circuit 1 is remarkable in that it comprises a plurality of copper diffusion barriers 6. Each barrier 6 extends as a thin layer against the contact surface 420 of a copper via 42. Thus copper diffusion to the non-volatile memories 5, 5′ is blocked.

It is possible for one or more, or even all, of the diffusion barriers to be planar, or even completely planar. This makes it possible to limit, or even avoid, large overall size along the direction Z, while preventing the barrier layer from bypassing the heating element or having to provide spacers. The plane in which these diffusion barriers are formed can be a horizontal plane (i.e. in the XY plane) or a vertical plane (i.e. orthogonal to the XY plane).

Unlike a tungsten plug, as implemented in prior art, each diffusion barrier 6 is made from tantalum or titanium or cobalt or alloys thereof. Said alloys are for example: TaN/Ta, TiN, TiC, TiSiN, TiSiCN, TaN or even TaCN. Said alloys may also comprise tungsten, such as TiWN. Barriers based on tantalum or titanium or cobalt or their material alloys offer a good capacity for blocking the diffusion of copper atoms even with a limited thickness. It is therefore possible to form diffusion barriers 6 in the form of very thin layers, much thinner than a tungsten plug according to prior art. In addition, tungsten plugs can be very rough, which may require chemical and/or mechanical polishing. As for the diffusion barriers 6, they may have a thickness, measured perpendicularly to the top surface 410 of the substrate, of between 0.5 nm and 20 nm. For example, a TaN/Ta barrier 6 may have a thickness of 13 nm.

Some materials require several layers in order to form an effective barrier 6. For example, in the case of TaN/Ta, deposition of a layer of TaN on copper enables a layer of Ta to be grown in an adapted crystalline phase. For example, each diffusion barrier 6 is a planar bilayer such that the planar bilayer comprises TaN in contact with the via 42 or row, and comprises Ta in contact with the heating element.

Diffusion barriers 6 preferably consist solely of TaN/Ta or TiN or TiC or TiSiN or TiSiCN or TaN or TaCN or Co, or even Ta or Ti. They can also be made of TiWN. In this way, the copper diffusion blocking is improved and the thickness of the barriers 6 can be further reduced. Even more preferably, the diffusion barriers 6 consist solely of TaN/Ta, TiN, TiC, TiSiN, TiSiCN, TaN or TaCN or even TiWN. These materials have the best blocking properties and can therefore be used to manufacture the thinnest layers.

According to one alternative embodiment, each diffusion barrier 6 can comprise cobalt Co. Indeed, the latter can be bonded to tungsten or phosphorus to improve its copper barrier qualities. Alternatively, each diffusion barrier is made of Co only. Cobalt also has a good capacity to block diffusion of copper atoms, even with a limited thickness. The advantage of materials such as cobalt lies in the ease with which the diffusion barriers 6 can be manufactured. Indeed, the copper contact surfaces 420 of the vias 42 (or rows) make it possible to perform selective deposition relative to the substrate and thus achieve layer growth at said contact surfaces 420. The diffusion barriers 6 thus obtained are aligned with the contact surfaces 420, without the need for any particular etching or delimiting step.

Other materials, based on tantalum or titanium, can also be used to grow barriers 6 without any particular etching or delimitation, provided that these materials can be deposited onto copper selectively relative to the substrate (for example relative to the dielectric making up the substrate).

Copper diffusion blocking is optimal when the diffusion barriers 6 extend over all the contact surfaces 420. For example, each diffusion barrier 6 can extend over the entire contact surface 420 and beyond, for example extending over the top surface 410 of the substrate 41. The diffusion barriers 6 thus form effective barriers.

Alternatively, the diffusion barriers 6 may cover only part of each contact surface 420 while providing sufficient copper diffusion blocking. Indeed, copper diffusion depends on the temperature considered and the lifetime of the integrated circuit 1.

In addition, when the diffusion barriers 6 cover only part of each contact surface 420, passivation of portions of the remaining contact surfaces 420 can be performed. In this way, the oxide film forming on the remaining surfaces 420 completes the diffusion barriers 6. A layer of SiN can, for example, be deposited to perform this passivation and complete the barriers 6.

Each diffusion barrier 6 provides a copper-free surface to which a non-volatile memory 5, 5′ can be connected. It therefore also provides electrical transport between a via 42 and a memory 5, 5′. For this, when the circuit 1 comprises several diffusion barriers 6, they are advantageously separated in order to avoid creation of a short circuit between two distinct vias 42 or memories 5, 5′.

In the embodiment of FIGS. 1A and 1B, each non-volatile memory 5, 5′ is connected to a diffusion barrier 6 through its heating element 52. In particular, the leg 522 of each heating element 52 extends over a diffusion barrier 6. The leg 522 may allow further reduction of copper diffusion by forming an overlay on the diffusion barrier 6.

Each memory 5, 5′ may have a first active layer 51, distinct from the first active layers 51 of the other memories. In the embodiment of FIGS. 1A and 1B, the memories 5, 5′ are arranged in groups of two. In particular, they are common in that each group of memories 5, 5′ has a common first active layer 51. Thus each first active layer 51 in FIGS. 1A and 1B is in electrical contact with two heating elements 52.

Each memory 5, 5′ has a top electrode 53 extending over the first active layer 51. This top electrode makes it possible, with the heating element 52, to flow an electric current in the first active layer 51, in order to perform the heat treatment of the first active layer 51.

In the embodiment of FIGS. 1A and 1B, the memories 5, 5′ have, two by two, a common first active layer 51 and a common top electrode 53, extending over the common first active layer 51. The phase change that can give rise to information storage is mainly in the electrical path between the point of contact with a heating element 52 and the top electrode 53. A sufficient distance between these two electrical paths allows independent operation of memories 5, 5′ sharing a same first active layer 51.

Alternatively, two distinct top electrodes 53 can extend over a same first active layer 51 in order to improve the separation of electrical paths.

The memories 5, 5′ of FIGS. 1A and 1B are electrically connected to a conductive track 7 extending in parallel to the top surface 410 of the substrate 41 and having protrusions connecting each top electrode 53.

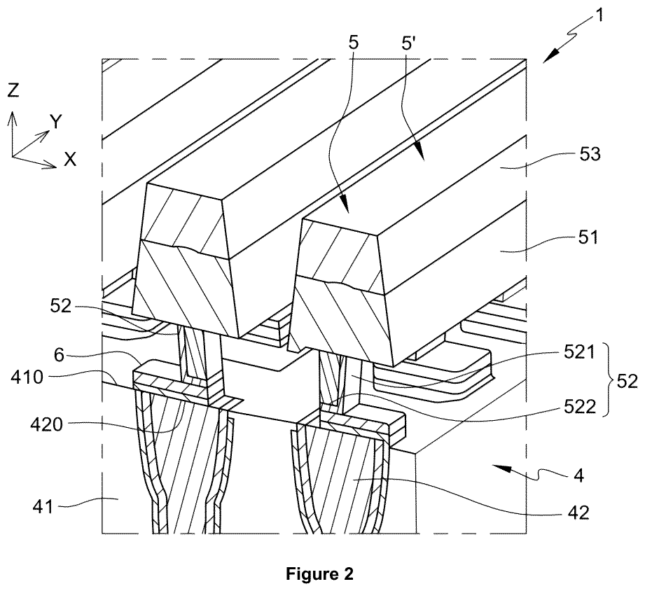

FIG. 2 shows a second embodiment of an integrated circuit 1 according to the invention. This figure shows the integrated circuit 1 from a perspective that allows distribution of the diffusion barriers 6 to be observed, arranged in a matrix of columns (extending along the direction Y) and rows (extending along the direction X). Each diffusion barrier 6 extends, in the form of a thin layer, over a via 42. It can be deduced from this that the vias 42 of the underlying routing level 4 are also arranged in this same matrix of columns and rows. In the case where the routing level 4 comprises rows rather than vias, the rows may extend into the substrate along the direction X.

The non-volatile memories 5, 5′ in FIG. 2 are also arranged in the matrix of columns and rows, each memory lying as an extension of a heating element 52. Unlike the embodiment of FIGS. 1A and 1B, where neighbouring memories 5, 5′ in a same row share a same first active layer 51, all the memories 5, 5′ of FIG. 2 arranged in the same column (i.e. along the direction Y) share a same first active layer 51. In the embodiment of FIGS. 1A and 1B, the memories 5, 5′ are said to form, two by two, “memory islands”, whereas in the embodiment of FIG. 2, the memories 5, 5′ are said to form, in each column, “memory columns” (or “memory rows” if they are arranged along the direction X).

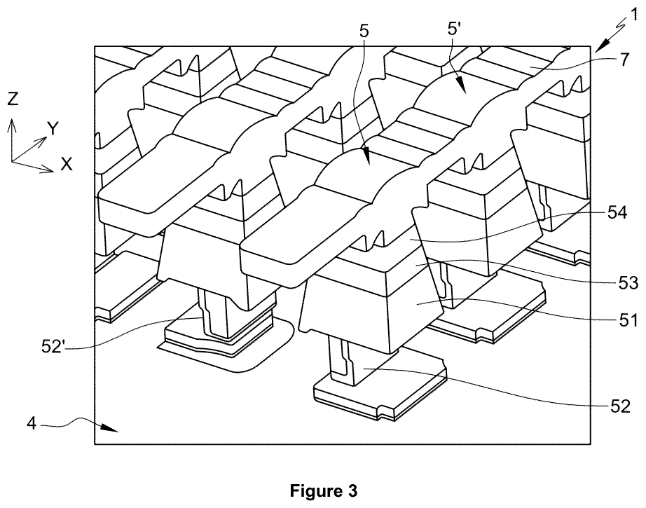

FIG. 3 shows a third embodiment of a circuit 1 according to the invention. Unlike the embodiments of FIGS. 1A, 1B and 2, the first active layers 51 of each memory 5, 5′ are distinct from each other. Likewise, the top electrodes 53 of each memory 5, 5′ are distinct from each other.

The circuit 1 also comprises a plurality of second active layers 54 extending in parallel to the top surface 410 of the substrate 41, electrically connected to the first active layers 51 by extending against each top electrode 53. This second active layer 54 acts, for example, as a selection element, also referred to as a “memory selector”. It can behave as an Ovonic Threshold Switching (OTS). For this, each second active layer 54 comprises, for example, an alloy based on Ge, Sb, Se, As, Si, Te, S or Al, which may be doped, such as GeSbSe, GeSe, AsSeSiGe, AsSe, SbSe, SiSe, AsTe, SiGeSe or AlTe alloys. The second active layer 54 may comprise any type of material enabling it to operate, according to different internal mechanisms, as a memory selector.

It is possible for the OTS (i.e. the second active layer) to be vertically aligned with the non-volatile memory 5, 5′. It is also or alternatively possible that the OTS (i.e. the second active layer) is co-integrated with the corresponding non-volatile memory.

The top electrode 53 between the two active layers 51, 54 of a memory 5, 5′ makes it possible to improve electrical contact between these two layers 51, 54 to make their behaviour reproducible and identical from memory to memory.

In FIG. 3, each conductive track 7 is connected to the memories 5, 5′ of a same column by extending against the second active layers 54 of each memory 5, 5′.

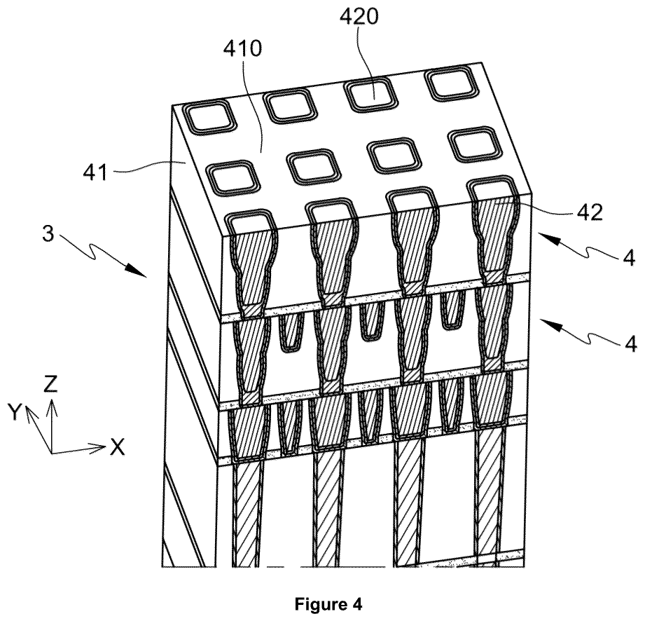

FIGS. 4 to 18 show a first mode of implementation of a method for manufacturing an integrated circuit 1 according to the invention.

FIG. 4 shows a step of providing a copper routing level 4. The routing level 4 comprises a substrate 41 and a plurality of copper vias 42. The substrate 41 has a planar surface 410. Each via 42 passes right through the substrate 41 and terminates on the planar surface 410 of the substrate 41 by exposing a contact surface 420. The planar surface 410 of the substrate 41 and the contact surfaces 420 can be levelled by Chemical Mechanical Planarisation (CMP).

The vias 42 of the routing level are arranged in a matrix of columns (along the direction Y) and rows (along the direction X).

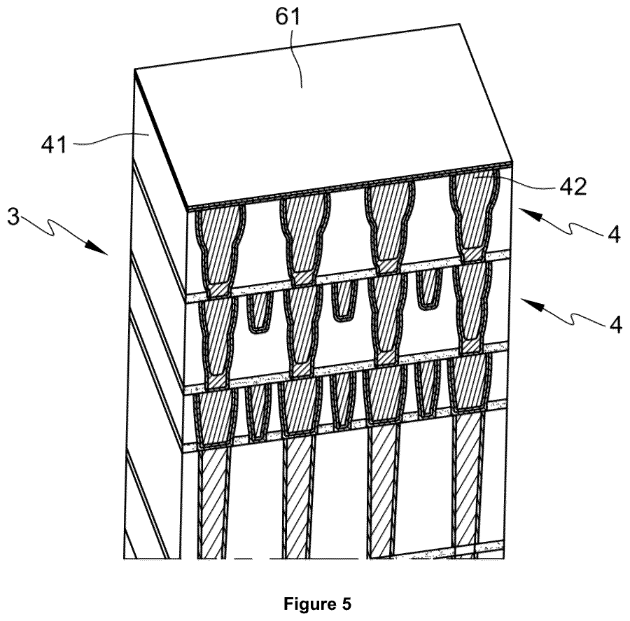

FIGS. 5 to 18 show several steps for forming a diffusion barrier 6 on each via 42. They also show, in conjunction with forming the diffusion barriers 6, forming the memories 5, 5′.

FIG. 5 shows a step of depositing a layer 61 of tantalum or titanium or cobalt or alloys thereof. These are, for example, so-called “ceramic” materials (such as TaN/Ta, TiN, TiC, TiSiN, TiSiCN, TiWN, TaN or TaCN alloys) or metal materials (Co-based, for example). For the remainder of the description, an implementation will be described in which a so-called “barrier” material is deposited, referring to any of the materials based on tantalum or titanium or cobalt or alloys thereof. The barrier material is deposited as a layer 61, referred to as a “barrier material layer”.

One, several or all of the diffusion barriers may be planar in shape, i.e. they are shaped so as to be planar in shape, or even to be completely planar in shape.

The barrier material layer 61 deposited covers the substrate 41 and the contact surfaces 420 of the vias 42. Some materials, such as TaN, may require the preliminary deposition of a layer of TaN onto the substrate 41 and the vias 42, to allow the deposition of a homogeneous layer of Ta in an adapted crystalline phase.

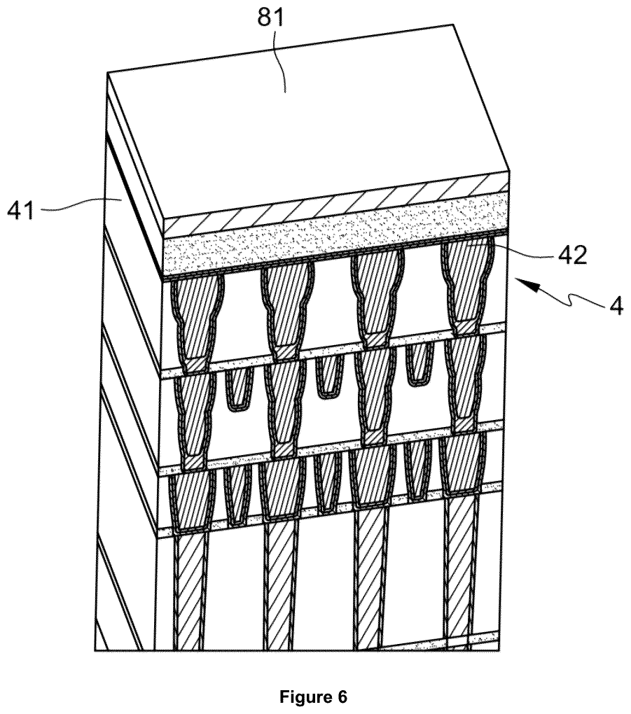

FIGS. 6 to 18 show the steps for forming, in parallel with forming the diffusion barriers 6, the heating elements 52. In particular, FIGS. 6 to 10 show forming a resistive layer 520, for forming at least one heating element 52 comprising a fin 521 extending perpendicularly to the barrier material layer 61 and in vertical alignment with a plurality of vias 42 aligned in a column. According to this manufacturing method, the heating element 52 also has a leg 522, extending against the layer 61 made of barrier material, also in vertical alignment with the same vias 42 aligned along the column.

For this, FIG. 6 shows a step of depositing a first dielectric material layer 81 onto the barrier material layer 61. The first dielectric layer 81 comprises, for example, a sublayer of SiN, extending against the barrier material layer 61, and a sublayer of SiO₂ extending over the layer of SiN.

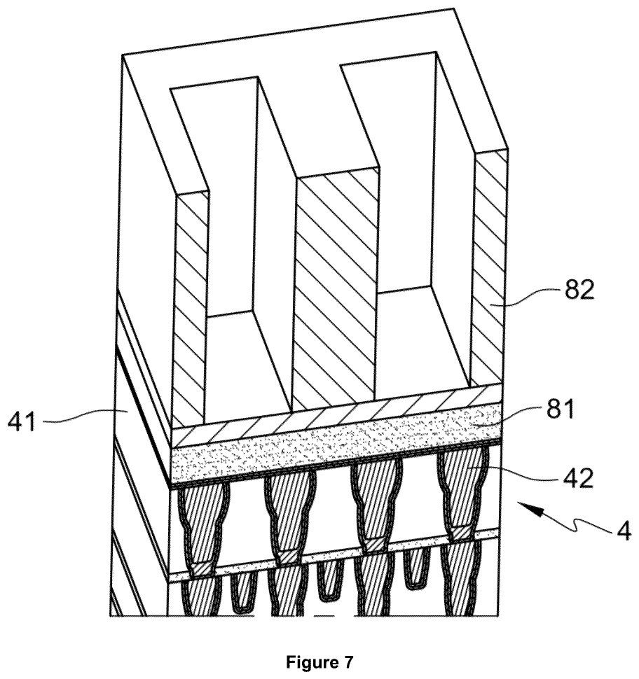

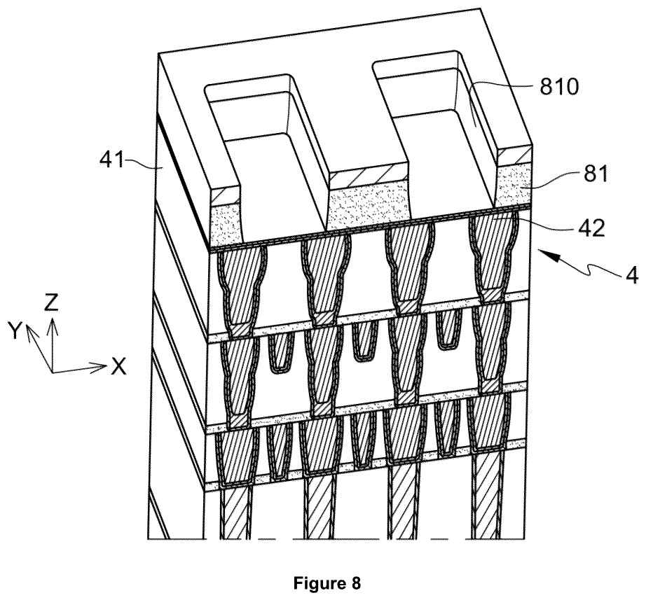

FIGS. 7 and 8 show a step of photolithography and etching of the first dielectric layer 81. The first dielectric layer 81 is etched through a temporary etch mask 82, with stopping on the barrier material layer 61, so as to form flanks 810 in the first dielectric layer 81. Each flank 810 is disposed in vertical alignment with at least one via 42. Herein in the example illustrated, the first dielectric layer 81 comprises four flanks 810, each extending in a column of vias 42 and in vertical alignment with these vias 42. The first dielectric layer 81 also reveals the barrier material layer 61. This etching can be made by means of a fluorinated plasma.

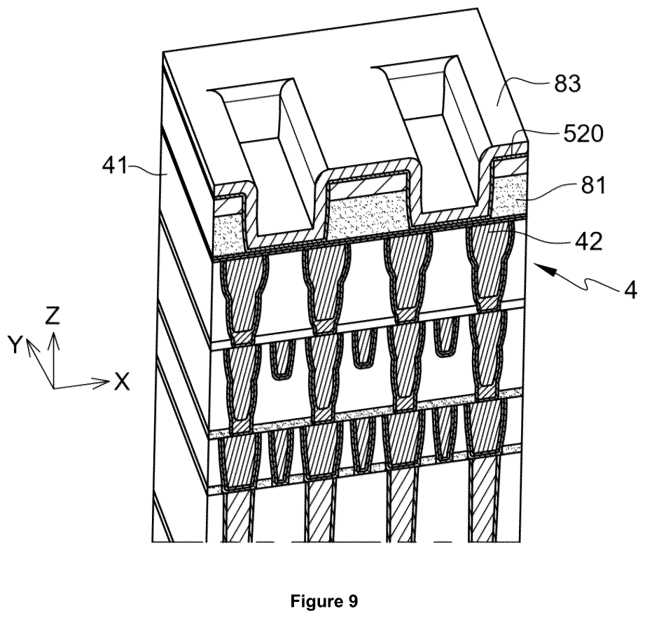

FIG. 9 shows a step of conformally depositing a resistive material layer 520 onto the first dielectric layer 81, including the flanks 810 thereof, and the exposed parts of the barrier material layer 61. The resistive layer 520 is made, for example, from TiN, TiC, TiSiN, TiSiCN, TiWN, TaN or TaCN.

FIG. 9 also shows the conformal deposition of a second dielectric layer 83, of SiN for example, onto the resistive layer 520. The thickness of the second dielectric layer 83 makes it possible to control the extent of the leg 522 of the heating element 52 along the direction X. The absence of the second dielectric layer 83 prevents the leg 522 from appearing. Its presence, however, protects the integrity of the fin 521 during etching of the resistive layer 520.

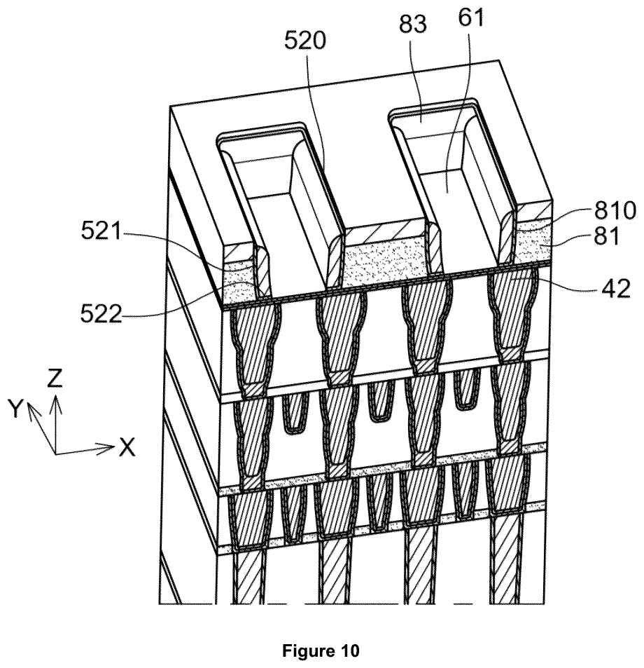

FIG. 10 shows a step of anisotropically etching the second dielectric layer 83 and the resistive layer 520. This etching is oriented perpendicularly to the planar surface 410 of the substrate 41 (in other words along −Z) with stopping on the barrier material layer 62. It can be performed by means of a fluorinated and chlorinated plasma. It especially delimits the fins 521 of the resistive layer 520, extending against the flank 810 of the first dielectric layer 81, and the legs 522 of the resistive layer 520, protected from the anisotropic etching by a part of the second dielectric layer 83 having a significant height (the height being measured along the direction Z).

The portions 521, 522 of the resistive layer thus extend in vertical alignment with the vias 42 arranged in one column.

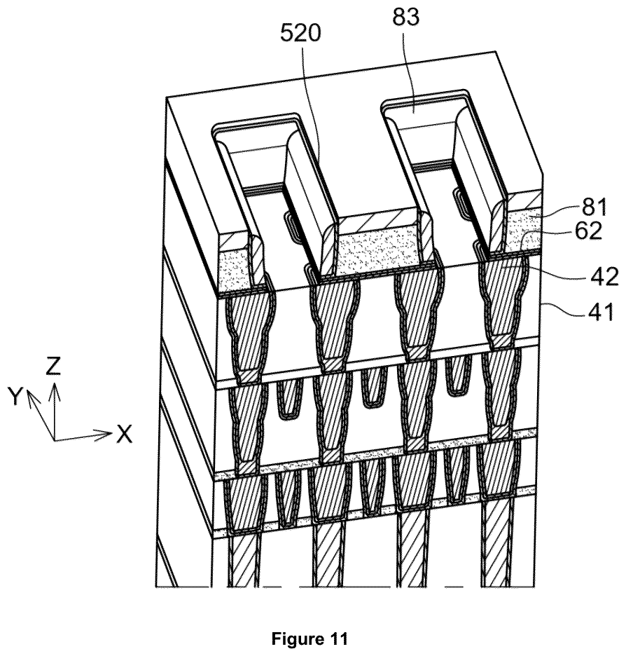

FIG. 11 shows an anisotropic etching of the barrier material layer 61 with stopping on the substrate 41. This etching is performed by employing the first dielectric layer 81, the remaining parts of the second dielectric layer 83 and the fins 521 of the resistive layer 520 as an etch mask. This etching delimits first strips 62 of barrier material in the barrier material layer 61. Each strip 62 extends against the contact surfaces 420 of vias 42 extending against two neighbouring columns. Typically, etching the barrier material layer is performed to form the diffusion barrier(s) at the contact surface.

Etching of the second dielectric layer 83, the resistive layer 520 and the barrier material layer 61 can be sequentially performed in a same step. Etching the barrier material layer 61 can also be performed by means of a fluorinated and chlorinated plasma.

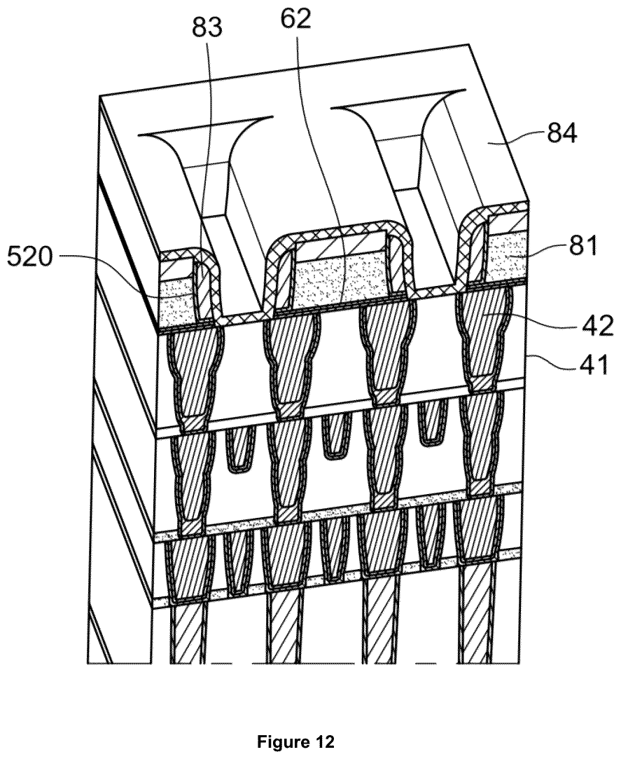

FIG. 12 shows conformally depositing a third dielectric layer 84, of SiN for example, onto all the elements. This third dielectric layer 84 makes it possible to passivate the legs 522 of the resistive layer 520 (if present), for forming the legs of the heating elements 52 of the memories 5.

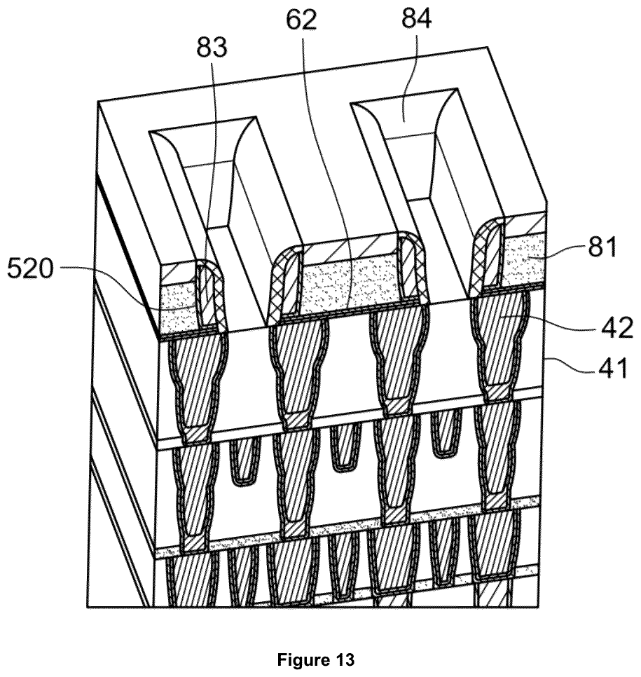

FIG. 13 shows anisotropic etching, by means of a fluorinated plasma for example, of the third dielectric layer 84 with stopping on the substrate 41. This etching removes the portions of the third dielectric layer 84 extending over the substrate 41 and joining two neighbouring legs 522 of the resistive layer 520. On the other hand, it leaves portions extending perpendicularly to the plane, against the remaining parts of the second dielectric layer 83 (themselves extending against the fins 521 of the resistive layer 520).

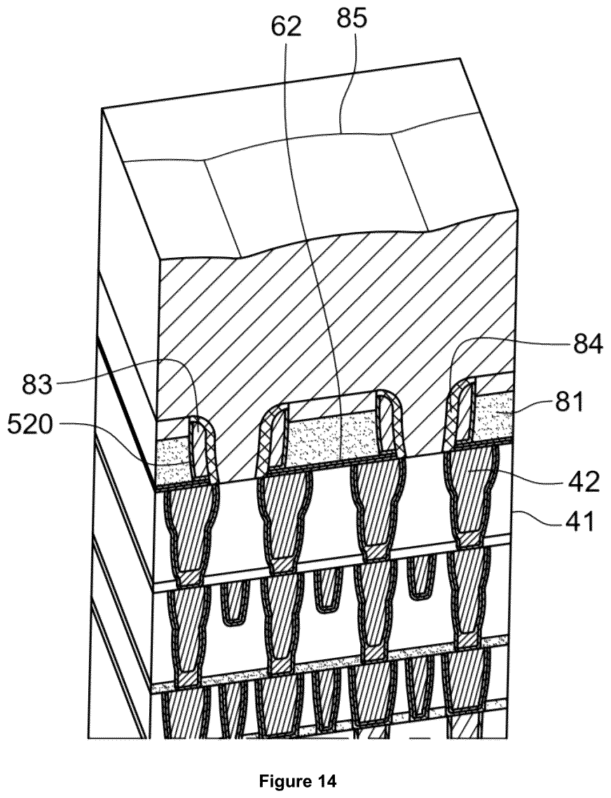

FIG. 14 shows a step of filling the cavities exposing the substrate 41. Filling is, for example, performed by depositing a fourth dielectric material 85, for example SiO₂, covering all the elements.

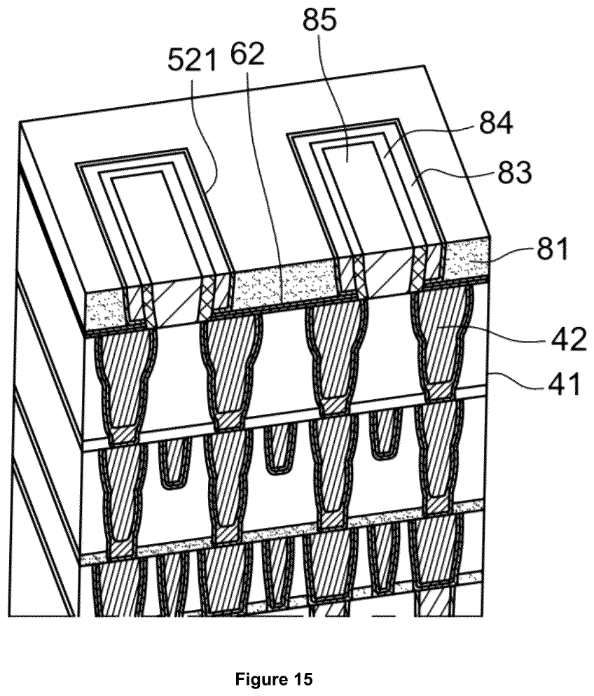

FIG. 15 shows a CMP planarisation step which exposes part of each fin 521 on which the first active layers 51 will be connected.

The advantage of partially etching the third dielectric layer 84, as illustrated in FIG. 13, is that the surface dielectric material is removed, which facilitates the CMP planarisation of FIG. 15. Indeed, it is simpler to planarise an oxide such as SiO₂ rather than a dielectric such as SiN. The result is a CMP planarisation of the oxide that is selective and with stopping on SiN that is controllable and reproducible in the sense of an industrialisable method.

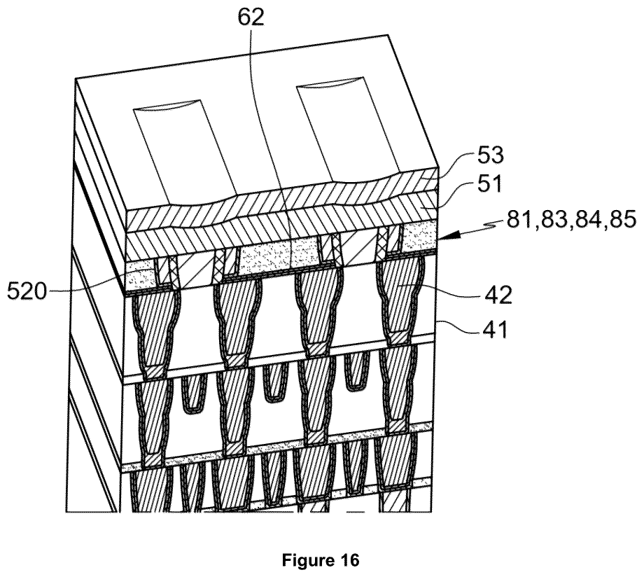

FIG. 16 shows a step of depositing the first active layer 51 is deposited against the fins 521 and against the dielectric layers 81, 83, 84 and 85 previously deposited. The first active layer 51 extends in parallel to the top surface 410 of the substrate 41.

FIG. 16 also shows a step of depositing a first metal layer 53, for forming the top electrodes, onto the first active layer 51.

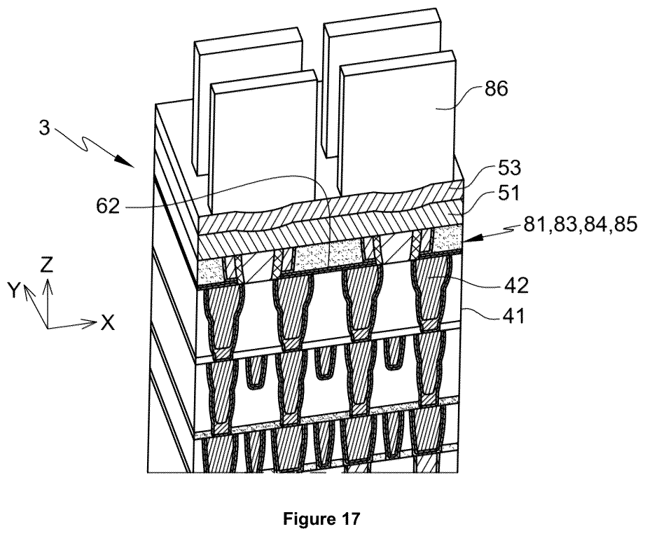

FIG. 17 shows a step of depositing a second etch mask 86 onto the first active layer 51 and the first metal layer 53. The second etch mask 86 has islands aligned with the rows and columns of vias 42, i.e. along directions X and Y. Each island is disposed and oriented so as to delimit, after etching, the diffusion barriers 6 and the memories 5, 5′.

For example, each island is disposed and oriented in such a way as to completely cover, by projection along Z, two neighbouring vias 46 of a same row. On the other hand, each of the islands completely covers, by projection along Z, only one via 46 of a same column. In this way, the islands expose portions of the resistive layer 520 and strips 62 of barrier material to etching.

The islands of the mask 86 are also spaced apart from each other. Herein, the islands of a same row (aligned along X) have a separation in vertical alignment with each strip 62 of barrier material, exposing other portions thereof to etching.

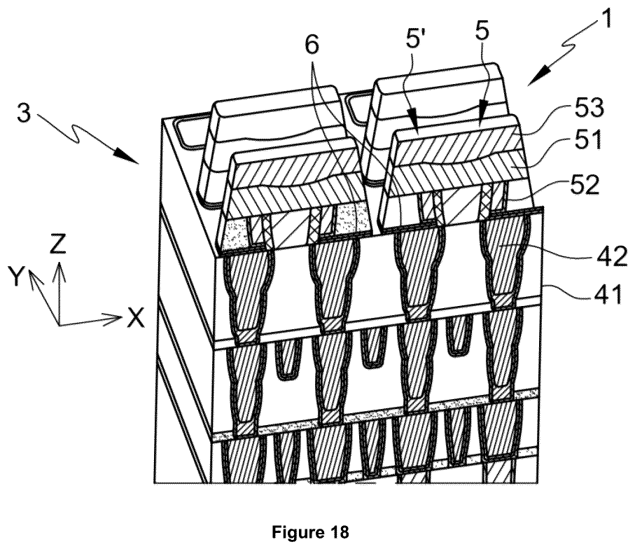

FIG. 18 shows the result of a step of anisotropically etching:
the first active layer 51;
the first metal layer 53;
the resistive layer 520; and
strips 62 of barrier material,
   which step is performed through the second etch mask 86 and especially through its islands, with stopping on the substrate 41. The resulting circuit corresponds to circuit 1 illustrated in FIGS. 1A and 1B.

The arrangement of the islands of the second mask 86 makes it possible to form, after etching, non-volatile memories 5, 5′ as illustrated by FIGS. 1A and 1B. Each island of the second etch mask 86, covering two vias 42 of a same row, makes it possible to form memories 5, 5′ of a same row whose first active layers 51 and top electrodes 53 are common.

Etching through the second etch mask 86 also enables the resistive layer 520 to be severed to delimit the heating elements 52 as an extension of each first active layer 51.

The combination of etching operations through the first mask (illustrated in FIG. 10, comprising the first and second dielectric layers 81, 83 and the resistive layer 520) with the second mask 86 delimits each heating element 52 and each diffusion barrier 6 as an extension from each other.

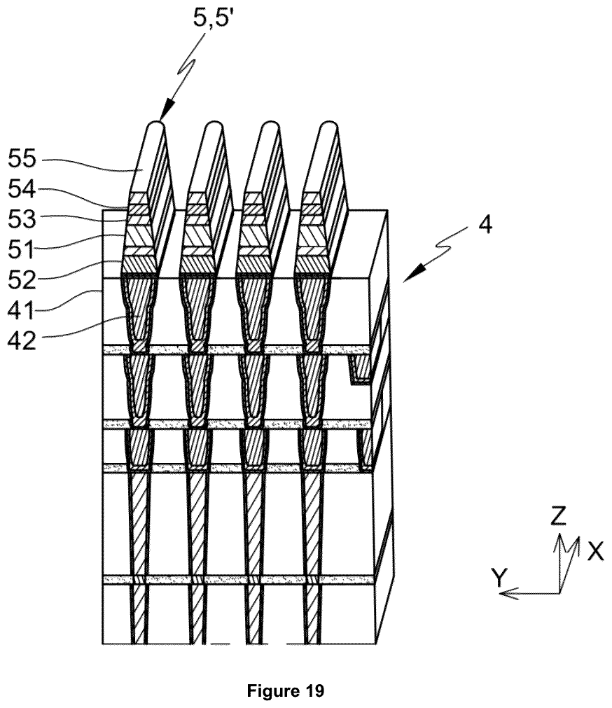

FIGS. 19 to 22 show additional steps that can be implemented using the cell 1 obtained by the step in FIG. 18. These additional steps make it possible to manufacture a selector, for example of OTS, for each memory 5, 5″ and to connect each selector to a conductive track 7. They especially make it possible to obtain the circuit 1 of FIG. 3.

FIG. 19 shows forming a second active layer 54 on each top electrode 53. The second active layer 54 is deposited, for example, in the step of FIG. 16, onto the first metal layer 53. Thus etching of FIG. 17 makes it possible to obtain a plurality of memories 5, 5′ with a first active layer 51, for example responsible for storing information, and a second active layer 54, for forming a selection element (also called a “selector”) for the first active layer 51. The materials indicated previously can be used to make this second active layer 54. In order to facilitate connection of the memories 5, 5′ to the conductive tracks 7, a second metal layer 55 can also be deposited onto the second active layer 54.

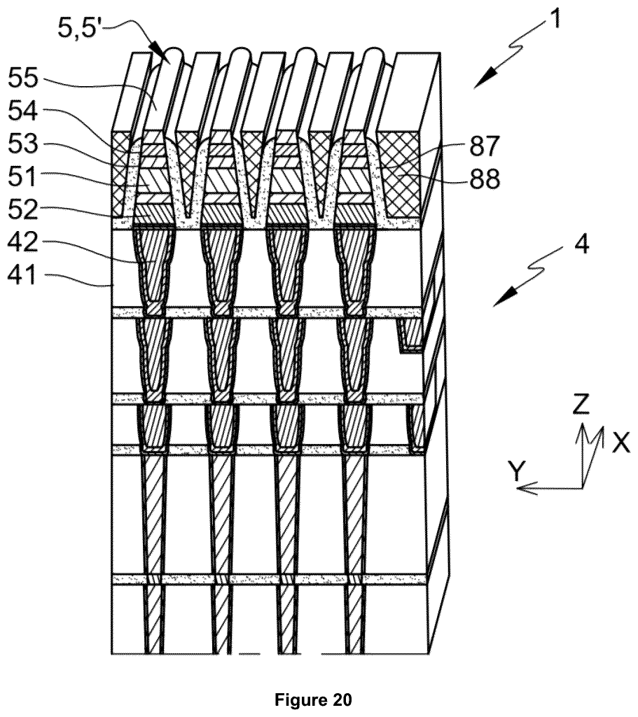

FIG. 20 shows encapsulation of the memories 5, 5′ comprising conformally depositing a fifth dielectric layer 87 against the sides of each memory 5, 5′ and the filling the cavities left by the encapsulation with a sixth dielectric layer 88, for example of SiO₂. The top of the memories 5, 5′ is released by means of a CMP planarisation step with stopping at the top of the memories 5, 5′, i.e. the second metal layer 55.

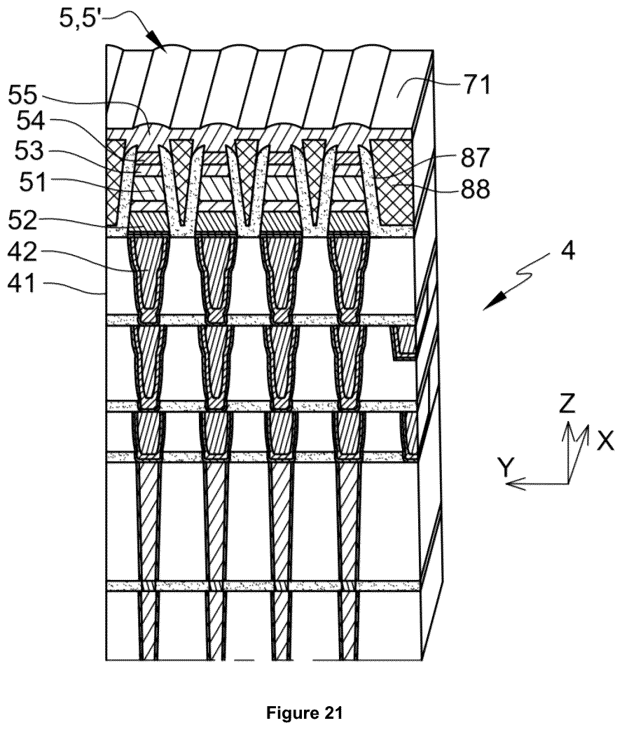

FIG. 21 shows depositing a third metal layer 71 for making the conductive tracks 7.

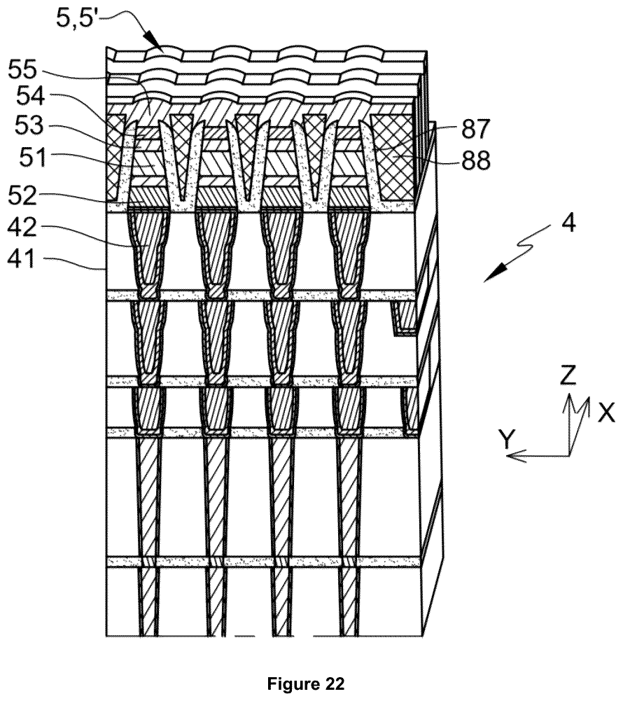

FIG. 22 shows a step of etching the third metal layer 71 and the different layers 51, 52, 53, 54, 55 of the memories 5, 5′. Etching is performed through a third etch mask aligned with the columns of the vias 42, with stopping on the substrate 41. This etching separates the memories 5, 5′ from each other (i.e. the first and second layers 51, 54 are distinct), each being connected to a conductive track 7.

A first alternative of implementation of the method consists in replacing deposition and etching operations aiming at forming the diffusion barriers 6 with a step of growing said barriers 6. Growing the barriers comprises, for example, a deposition step selectively to the substrate 41. Materials used to perform selective deposition therefore comprise any type of Ta, Ti or Co-based material enabling selective deposition. These include, for example, the so-called “ceramic” materials as set forth previously (for example TaN/Ta, TiN, TiC, TiSiN, TiSiCN, TiWN, TaN or even TaCN) or metal materials, such as titanium or tantalum or cobalt. Selectively depositing a compatible material relative to the substrate 41 thus makes it possible to grow barriers from each contact surface 420 of the vias 42, opening onto the substrate 41. It is therefore no longer necessary to resort to an etching step to delimit and align the barriers 6 with the vias 42.

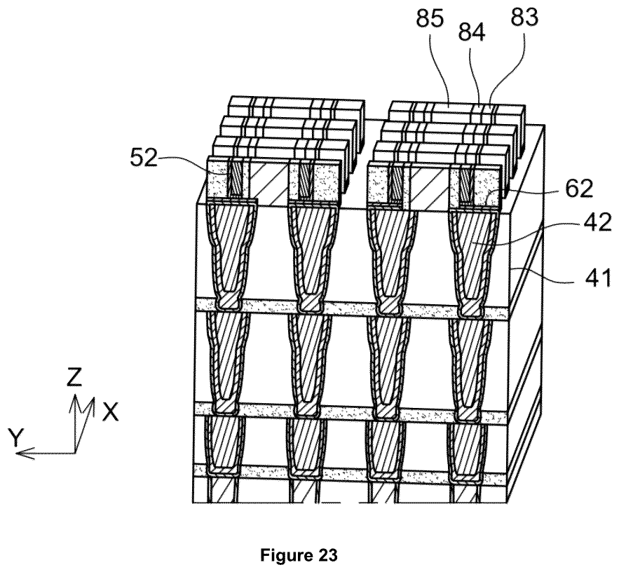

FIGS. 23 to 25 show one alternative implementation of the manufacturing method, especially FIGS. 16 to 18. This alternative achieves the circuit of FIG. 2.

Before depositing the first active layer 51 and the first metal layer 53, this alternative provides etching of the stack of FIG. 15 through an etch mask, with stopping on the substrate 41. The result of etching is illustrated in FIG. 23. It delimits each heating element 52 and each diffusion barrier 6, as an extension of each other. The etch mask employed to perform etching is similar to the second etch mask 86 illustrated in FIG. 17, especially comprising islands.

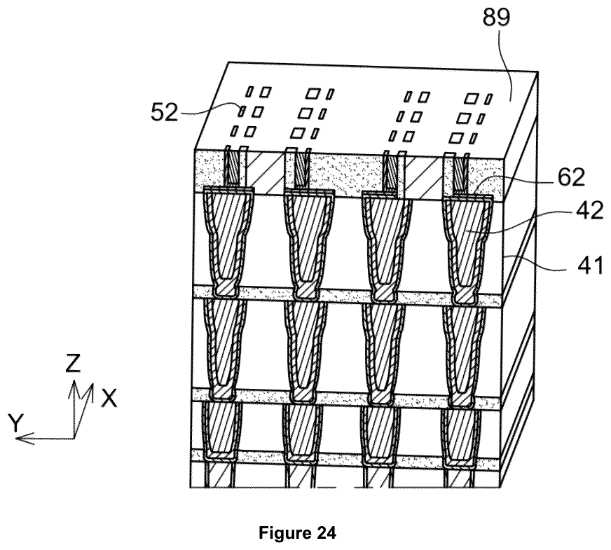

FIG. 24 shows the result of a step of depositing a seventh dielectric layer 89, of SiN for example, and a CMP planarisation with stopping at the top of the heating elements 52.

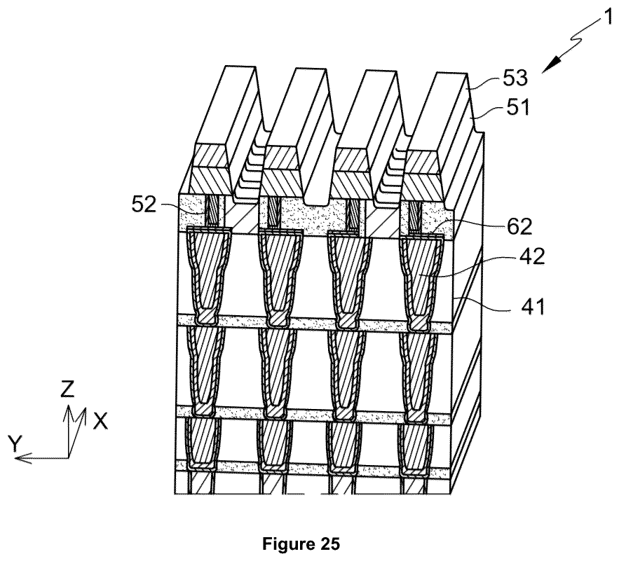

FIG. 25 shows the circuit 1 obtained subsequently to depositing a first active layer onto the stack of FIG. 24 and etching it so as to form rows of first active layer 51, extending against the heating elements 52 of a same row.

1. An integrated circuit comprising:
a substrate having a planar surface;
at least one via or row, of copper, extending in the substrate and opening onto the planar surface of the substrate, by exposing a surface referred to as the “contact surface”;
at least one non-volatile memory comprising:
a first electrode, referred to as the “heating element”;
a second electrode, referred to as the “top electrode”; and
a first active layer between the heating element and the top electrode, electrically connected to the top electrode and to the heating element,
at least one copper diffusion barrier based on tantalum or titanium or cobalt or an alloy thereof, said at least one diffusion barrier extending in the form of a layer against at least one part of the contact surface of said at least one via or of said at least one row, the at least one diffusion barrier being completely planar in shape, the heating element of said at least one non-volatile memory being in contact with the first active layer of said at least one non-volatile memory and in contact with said at least one diffusion barrier.

2. The integrated circuit according to claim 1, wherein, for each non-volatile memory, each heating element comprises a portion, referred to as a “fin”, extending perpendicularly to the surface of the substrate and comprising a first end, in contact with the first active layer of said non-volatile memory, and a second end, in contact with said at least one diffusion barrier.

3. The integrated circuit according to claim 1, wherein each diffusion barrier extends against the entire contact surface of said at least one via or of said copper row.

4. The integrated circuit according to claim 1, wherein each heating element comprises a material from: TiN, TiC, TiSiN, TiSiCN, TiWN, TaN and TaCN.

5. The integrated circuit according to claim 1, wherein the first active layer of each volatile memory comprises a chalcogenide material.

6. The integrated circuit according to claim 1, comprising:
a plurality of non-volatile memories; and
a plurality of diffusion barriers, spaced apart from each other;
a plurality of copper vias or copper rows, each via or row extending in the substrate and opening onto the surface of the substrate by exposing a contact surface, said contact surfaces being arranged in a matrix,
each diffusion barrier extending as a layer against at least one part of the contact surface of one of the vias or one of the rows, the heating element of each non-volatile memory being connected to one of the diffusion barriers.

7. The integrated circuit according to claim 1, wherein the first active layers of the different non-volatile memories are laterally insulated from each other.

8. The integrated circuit according to claim 1, wherein the same first active layer is continuous and common to at least two non-volatile memories, said same first active layer being in contact with each heating element of said at least two non-volatile memories.

9. The integrated circuit according to claim 1, comprising a selection element associated with said at least one non-volatile memory, the selection element being an ovonic threshold switch referred to as an “OTS”, the OTS being vertically aligned with the non-volatile memory.

10. The integrated circuit according to claim 1, devoid of tungsten via or metal via in contact with said at least one copper via or said at least one copper row and the heating element of said at least one non-volatile memory.

11. The integrated circuit according to claim 1, wherein the at least one diffusion barrier is a planar bilayer, the planar bilayer comprising TaN in contact with the via or the row, and comprising Ta in contact with the heating element.

12. A method for manufacturing an integrated circuit comprising:
providing:
a substrate having a planar surface; and
at least one via or at least one row, of copper, extending in the substrate and opening onto the planar surface of the substrate, by exposing a surface referred to as the “contact surface”,
forming at least one copper diffusion barrier based on tantalum or titanium or cobalt or alloys thereof, so that said at least one diffusion barrier extends in the form of a layer against at least one part of the contact surface of said at least one via or of said at least one row, the at least one diffusion barrier being completely planar in shape;
forming at least one non-volatile memory comprising:
a first electrode, referred to as the “heating element”, being in contact with said at least one diffusion barrier;
a second electrode, referred to as the “top electrode”; and
a first active layer between the heating element and the top electrode, electrically connected to the top electrode and in contact with the heating element.

13. The manufacturing method according to claim 12, wherein manufacturing each diffusion barrier comprises a step of growing said diffusion barrier by selectively depositing tantalum or titanium or cobalt or alloys thereof onto the contact surface of a copper via or a copper row.

14. The manufacturing method according to claim 12, wherein manufacturing the diffusion barrier comprises:
depositing a layer based on tantalum or titanium or cobalt or alloys thereof, referred to as a “barrier material layer”, onto the planar surface of the substrate and the contact surface of said at least one via or of said at least one copper row;
etching the barrier material layer through at least one etch mask, with stopping on the substrate, so as to form the at least one diffusion barrier at the contact surface.

15. The manufacturing method according to claim 14, wherein forming each non-volatile memory comprises:
forming, before the step of etching the barrier material layer, a first dielectric layer extending over the barrier material layer, leaving free at least one portion of the barrier layer, said first dielectric layer comprising at least one flank extending perpendicularly to the planar surface of the substrate, in vertical alignment with the contact surface of said at least one via or of said at least one row;
conformally depositing a resistive layer onto the first dielectric layer and onto said at least one free portion of the barrier layer;
anisotropically etching the resistive layer, perpendicularly to the planar surface of the substrate, with stopping on the barrier layer, so as to leave a portion of the resistive layer, referred to as a “fin”, extending perpendicularly to the planar surface of the substrate, from the barrier layer, against the flank of the first dielectric layer and in vertical alignment with the contact surface of said at least one via or of said at least one row;
anisotropically etching the barrier material layer through a first etch mask, with stopping on the substrate, the first etch mask comprising the first dielectric layer and the fin;
anisotropically etching the fin and the barrier material layer through a second etch mask, with stopping on the substrate, so as to delimit each diffusion barrier from the barrier material layer, at a part of the contact surface of said at least one via or of said at least one row, and so as to delimit each first electrode, referred to as the “heating element”, from the fin, as an extension of a diffusion barrier.

16. The manufacturing method according to claim 15, wherein forming each non-volatile memory comprises:
depositing, before etching the fin and the barrier material layer through the second etch mask, a first active layer extending in parallel to the planar surface of the substrate and in contact with each fin;
etching the first active layer through the second etch mask so as to delimit the first active layer in the extension of a heating element and a diffusion barrier.

17. The method according to claim 12, wherein the at least one diffusion barrier is etched a first time along a first direction upon forming the heating element, and a second time along a second direction, different from the first direction, upon forming the top electrode.
